(19) United States
(12) Patent Application Publication
(10) Pub. No.: US 2025/0386582 A1
(43) Pub. Date: Dec. 18, 2025

(54) SEMICONDUCTOR DEVICE

(71) Applicant: Samsung Electronics Co., Ltd., Suwon-si (KR)

(72) Inventors: Hyouk-Sang Yun, Suwon-si (KR); Sejun Park, Suwon-si (KR)

(21) Appl. No.: 19/007,821

(22) Filed: Jan. 2, 2025

(30) Foreign Application Priority Data
Jun. 14, 2024 (KR) 10-2024-0077792

(51) Int. Cl. H10D 64/66; H10B 43/40; H10D 64/27; H10D 84/01; H10D 84/83

(52) U.S. Cl. CPC H10D 64/662; H10B 43/40; H10D 64/517; H10D 64/663; H10D 84/83135; H10D 84/014

(57) ABSTRACT

A semiconductor device includes an active area on a substrate, a gate insulating layer on the active area, and a gate electrode structure on the gate insulating layer. The gate electrode structure includes a first blocking impurity-doped layer in contact with an upper surface of the gate insulating layer and doped with a blocking impurity, a middle layer on the first blocking impurity-doped layer, and a second blocking impurity-doped layer on the middle layer and doped with the blocking impurity. A blocking impurity concentration in the second blocking impurity-doped layer is higher than a blocking impurity concentration in the first blocking impurity-doped layer.

### CROSS-REFERENCE TO RELATED APPLICATION(S)

This application claims the benefit of Korean Patent Application No. 10-2024-0077792, filed on Jun. 14, 2024, in the Korean Intellectual Property Office, the disclosure of which is incorporated herein by reference.

### BACKGROUND

The present disclosure relates generally to a semiconductor device and, more particularly, to a semiconductor device including a gate electrode structure providing enhanced performance.

A gate insulating layer and a gate electrode may be formed above an active area of a transistor, such as a metal-oxide-semiconductor field-effect transistor (MOSFET), included in a semiconductor device. Here, the gate electrode may include polysilicon containing a conductive impurity (hereinafter, referred to as a dopant) such as boron (B).

When the semiconductor device is to be highly integrated and have high performance, the gate insulating layer is required to be formed thinly. This arrangement may result in dopant penetration on the gate insulating layer.

### SUMMARY

An aspect of the present inventive concept provides a semiconductor device including a gate electrode structure for improving element performance while preventing dopant penetration.

Another aspect also provides a semiconductor device for preventing pitting from occurring in an active area of a circuit near a gate electrode structure in an etching process.

However, the goals to be achieved by example embodiments of the present disclosure are not limited to the objectives described above and other objects may be clearly understood from the following example embodiments by those skilled in the art.

According to an aspect, there is provided a semiconductor device including an active area formed on a substrate, a gate insulating layer on the active area, and a gate electrode structure on the gate insulating layer. The gate electrode structure includes a first blocking impurity-doped layer in contact with an upper surface of the gate insulating layer and doped with a blocking impurity, a middle layer on the first blocking impurity-doped layer, and a second blocking impurity-doped layer on the middle layer and doped with the blocking impurity. A blocking impurity concentration in the second blocking impurity-doped layer is higher than a blocking impurity concentration in the first blocking impurity-doped layer.

According to another aspect, there is also provided a semiconductor device including an active area formed on a substrate, a gate insulating layer on the active area, and a gate electrode structure comprising a polysilicon layer on the gate insulating layer. The polysilicon layer of the gate electrode structure includes a lower area in contact with an upper surface of the gate insulating layer and comprising a blocking impurity, an upper area formed on the lower area and comprising the blocking impurity, and a middle area formed between the upper area and the lower area, a blocking impurity concentration in the lower area is higher than a blocking impurity concentration in the middle area, and a blocking impurity concentration in the upper area is higher than the blocking impurity concentration in the lower area.

According to still another aspect, there is also provided a semiconductor device including an active area formed on a substrate, a gate insulating layer on the active area, and a gate electrode structure on the gate insulating layer. The gate electrode structure includes a first blocking impurity-doped layer on the gate insulating layer and doped with a blocking impurity, a middle layer on the first blocking impurity-doped layer, and a second blocking impurity-doped layer on the middle layer and doped with the blocking impurity. The first blocking impurity-doped layer includes first grains, the second blocking impurity-doped layer includes second grains, and an average size of the second grains is smaller than an average size of the first grains.

Additional aspects of example embodiments will be set forth in part in the following description and drawings.

According to example embodiments, it is possible to implement, through a gate electrode structure formed as a plurality of layers doped with a blocking impurity in different concentrations, a semiconductor device including the gate electrode structure which may improve element performance while preventing dopant penetration.

According to example embodiments, it is possible to implement, through the gate electrode structure formed as the plurality of layers doped with the blocking impurity in the different concentrations, a semiconductor device for preventing pitting from occurring in an active area of a circuit near the gate electrode structure in an etching process.

Effects of the present disclosure are not limited to those described above and may vary within the scope of the technical spirit and extent of the present disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings, wherein like reference numerals (when used) indicate corresponding elements throughout the several views, and in which:

FIG. 1 is a schematic plan view illustrating a semiconductor device according to example embodiments;

FIG. 2A is an example schematic cross-sectional view taken along line A-A′ of FIG. 1;

FIG. 2B is a graph illustrating an example of an average size of grains of each layer included in a gate electrode structure of FIG. 2A;

FIG. 3A is an example cross-sectional view taken along line A-A′ of FIG. 1;

FIG. 3B is a graph illustrating an example of a blocking impurity concentration in a middle layer of FIG. 3A;

FIG. 4A is an example schematic cross-sectional view taken along line A-A′ of FIG. 1;

FIG. 4B is a graph illustrating an example of a blocking impurity concentration in a middle layer of FIG. 4A;

FIG. 5 is an example schematic cross-sectional view illustrating a semiconductor device according to example embodiments;

FIG. 6 is an example schematic cross-sectional view illustrating a semiconductor device according to example embodiments;

FIGS. 7 through 14 are schematic cross-sectional views depicting intermediate processes for describing a method of manufacturing a semiconductor device according to example embodiments; and

FIG. 15 is an example schematic cross-sectional view illustrating a vertical-type semiconductor device according to example embodiments.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their invention in the best way. Thus, since the example embodiments described in the present disclosure and configurations illustrated in the accompanying drawings are merely most desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form are intended to include terms in a plural form as well unless an apparently and contextually conflicting description is present. Terms such as “including” or “comprising” is intended to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on relative orientations illustrated in the drawings and that the expression may be changed when an orientation of a corresponding object is changed. Shapes, sizes, or the like of elements in the drawings may be exaggerated for clearer description; that is, dimensions of one or more elements shown in the drawings may not necessarily be drawn to scale.

Hereinafter, a semiconductor device according to the example embodiments will be described with reference to the accompanying drawings.

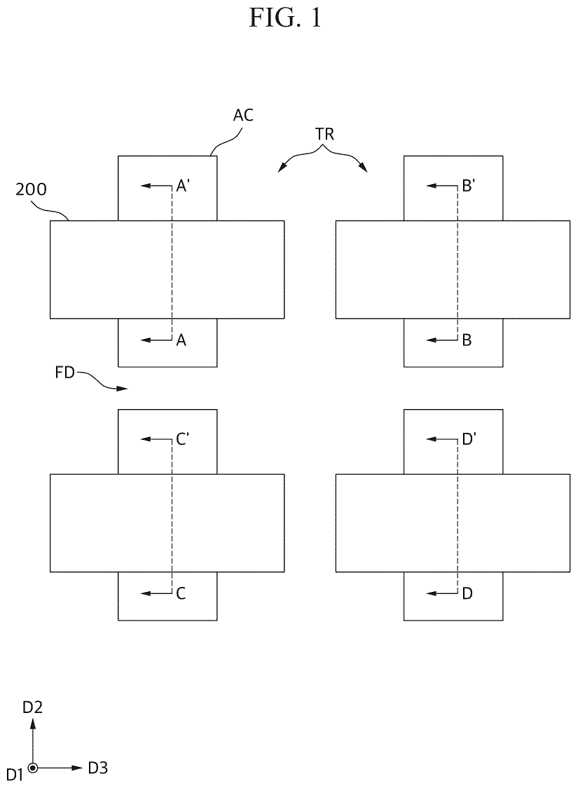

FIG. 1 is a schematic plan view illustrating a semiconductor device according to example embodiments.

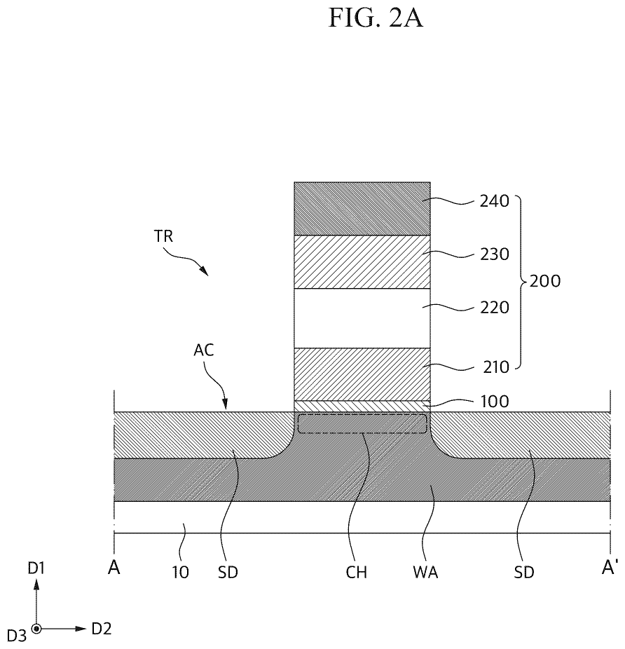

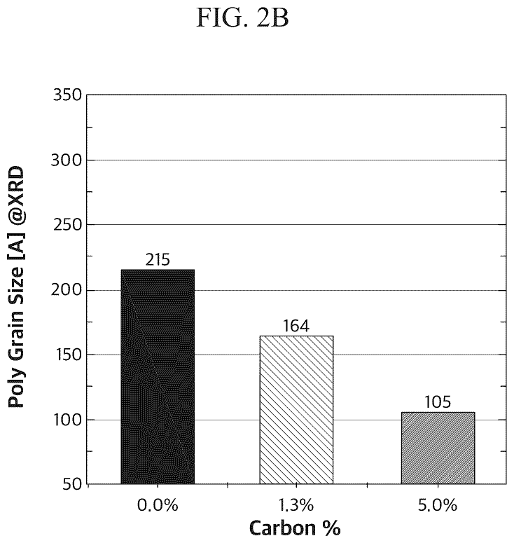

FIG. 2A is an example schematic cross-sectional view taken along line A-A′ of FIG. 1.

FIG. 2B is a graph illustrating an example of an average size of grains of each layer included in a gate electrode structure 200 of FIG. 2A.

Referring to FIGS. 1 and 2A together, the semiconductor device includes an active area AC formed on a substrate 10 and a plurality of transistors TR including the gate electrode structure 200 which is disposed above the active area AC.

In example embodiments, the substrate 10 may be formed of a semiconductor substrate 10. In example embodiments, the substrate 10 may include single crystal silicon. Alternatively, the substrate 10 may be a silicon-on-insulator (SOI) substrate 10 or a germanium-on-insulator (GOI) substrate 10.

The substrate 10 may include the active area AC and a field area FD. A trench for element separation and an element separation film that fills an inside of the trench for element separation may be provided in the field area FD of the substrate 10. The term “fills” (or “fill,” or like terms) is intended to refer to either completely filling a defined space (e.g., the trench for element separation) or partially filling the defined space; that is, the defined space need not be entirely filled but may, for example, be partially filled or have voids or other spaces throughout. The active area AC may be defined by the trench for element separation and the element separation film which fills the trench for element separation. The trench for element separation may have a side wall inclination so that an inner width becomes narrow in a direction from an upper part toward a lower part. However, a detailed structure thereof is not limited to the above description.

In example embodiments, the active area AC may include a well area WA and a pair of source/drain areas SD surrounded by the wall area WA. The term “surrounded” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The well area WA and a source/drain area SD may be areas doped with conductivity-type dopants opposite to each other. For example, the well area WA may be an area doped with a p-type impurity, and the pair of source/drain areas SD may be an area doped with an n-type impurity. Alternatively, on the contrary, the well area WA may be the area doped with the n-type impurity, and the pair of source/drain areas SD may be the area doped with the p-type impurity.

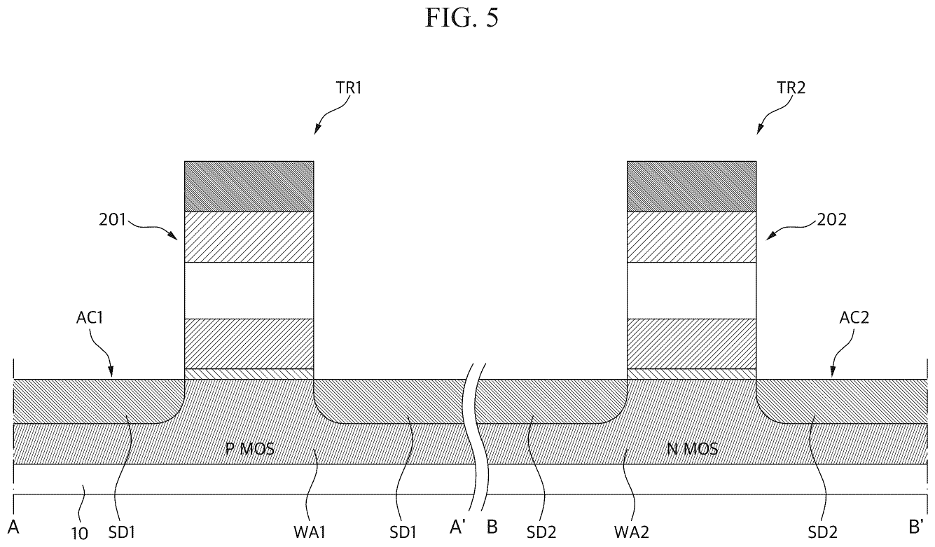

In example embodiments, multiple active areas AC may be formed on the substrate 10. For example, the active area AC may include a first active area (e.g., a first active area AC1 of FIG. 5) and a second active area (e.g., a second active area AC2 of FIG. 5) that are doped with conductivity-type dopants opposite each other. In this case, the gate electrode structure 200 may be disposed on each of the first active area AC1 and the second active area AC2.

In example embodiments, the gate electrode structure 200 may be disposed between the pair of source/drain areas SD on the active area AC. At least a portion of the gate electrode structure 200 may be disposed to overlap the active area AC in a first direction. As used herein, “an element A overlapping an element B in a direction X” (or similar language) means that there is at least one line that extends in the direction X and intersects both the elements A and B. A channel area CH may be formed in a lower part of a gate structure in the active area AC.

In example embodiments, a gate insulating layer 100 may be interposed between the active area AC and the gate electrode structure 200. The gate insulating layer 100 may be formed of a silicon oxide film, but it is merely an example. For example, the gate insulating layer 100 may include silicon oxynitride, silicon nitride, or a high-permittivity material having a dielectric constant higher than that of silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

In example embodiments, the gate electrode structure 200 may have a multilayer structure in which a metallic conductive layer 240 is disposed above polysilicon layers 210, 220, and 230 doped with a conductivity-type dopant. For example, a polysilicon layer forming the gate electrode structure 200 may be doped with the p-type impurity or the n-type impurity depending on a channel type of a transistor TR. For example, when the transistor TR is a p-channel metal-oxide-semiconductor (PMOS) transistor, the gate electrode structure 200 may include a polysilicon layer doped with the p-type impurity. When the transistor TR is an n-channel metal-oxide-semiconductor (NMOS) transistor, the gate electrode structure 200 may include a polysilicon layer doped with the n-type impurity.

In example embodiments, the polysilicon layers 210, 220, and 230 of the gate electrode structure 200 may be distinguished into a plurality of areas having different blocking impurity concentrations (i.e., impurity doping concentration levels). Here, a blocking impurity may be a material for blocking penetration of the conductivity-type dopant, with which the gate electrode structure 200 is doped, into the gate insulating layer 100 and the active area AC thereunder. For example, the blocking impurity may be a material including at least one of carbon and germanium.

Referring to FIG. 2A, the gate electrode structure 200 may include a first blocking impurity-doped layer 210 and a second blocking impurity-doped layer 230 each formed of polysilicon doped with the blocking impurity and include a middle layer 220 disposed in between and formed of polysilicon not doped with the blocking impurity.

In example embodiments, the first blocking impurity-doped layer 210, the middle layer 220, and the second blocking impurity-doped layer 230 may be some areas distinguished in a height (i.e., vertical) direction (e.g., a D1 direction), perpendicular to an upper surface of the substrate 10, in an area formed of polysilicon in the gate electrode structure 200. For example, in the following description, the first blocking impurity-doped layer 210, the middle layer 220, and the second blocking impurity-doped layer 230 may be understood as corresponding to a lower area, a middle area, and an upper area among areas formed of the polysilicon layer in the gate electrode structure 200, respectively. In addition, a boundary line is illustrated for distinguishing the first blocking impurity-doped layer 210, the middle layer 220 and the second blocking impurity-doped layer 230 in FIG. 2A. However, the first blocking impurity-doped layer 210, the middle layer 220, and the second blocking impurity-doped layer 230 may correspond to some areas distinguished in the vertical direction (e.g., the D1 direction) in a single polysilicon layer, and a clear boundary surface as illustrated in a drawing (e.g., FIG. 2A) may not be formed in between.

In example embodiments, the first blocking impurity-doped layer 210 and the second blocking impurity-doped layer 230 may have different blocking impurity concentration levels. For example, a blocking impurity concentration in the first blocking impurity-doped layer 210 which is adjacent to the gate insulating layer 100 may be lower than a blocking impurity concentration in the second blocking impurity-doped layer 230.

In example embodiments, the first blocking impurity-doped layer 210 may have a blocking impurity concentration less than or equal to approximately three percent. Desirably, in some embodiments the first blocking impurity-doped layer 210 may have a blocking impurity concentration less than or equal to one percent. The first blocking impurity-doped layer 210 which is doped with the blocking impurity as such may prevent deterioration of a characteristic of the semiconductor device by preventing a conductive dopant such as a boron (B) ion from diffusing into the gate insulating layer 100 and the underlying active area AC.

In example embodiments, the second blocking impurity-doped layer 230 may have a blocking impurity concentration greater than or equal to approximately three percent. Desirably, in some embodiments the second blocking impurity-doped layer 230 may have a blocking impurity concentration of approximately five percent. The second blocking impurity-doped layer 230 which is doped with the blocking impurity as such may have a stronger tolerance in an etching process. Through this, pitting in which the active area AC is pitted as both sides of the gate electrode structure 200 are excessively etched in the etching process may be prevented.

In example embodiments, the first blocking impurity-doped layer 210 may include first grains, the second blocking impurity-doped layer 230 may include second grains, and an average size of the second grains may be smaller than an average size of the first grains. In other words, an average grain size of the first blocking impurity-doped layer 210 which has a relatively low blocking impurity concentration may be smaller than an average grain size of the second blocking impurity-doped layer 230 which has a relatively high blocking impurity concentration. Also, the average grain size of the first blocking impurity-doped layer 210 doped with the blocking impurity may be larger than an average size of third grains included in the middle layer 220 which is not doped with the blocking impurity. Referring to FIG. 2B, an average grain size of the middle layer 220 which is not doped with carbon may be approximately 215 angstroms (Å). The average grain size of the first blocking impurity-doped layer 210 which has a carbon concentration of approximately one point three percent may be approximately 164 Å that is smaller than that of the middle layer 220. Furthermore, the average grain size of the second blocking impurity-doped layer 230 which has a carbon concentration of approximately five percent may be approximately 105 Å. As such, it may be understood that a grain size is gradually decreased as a blocking impurity concentration in the polysilicon layer is increased.

However, an average grain size of each of the above-described layers (or areas) of the gate electrode structure 200 is not limited to the above description. For example, the blocking impurity which is diffused from the adjacent first blocking impurity-doped layer 210 or the adjacent second blocking impurity-doped layer 230 may be partially present in the middle layer 220 in a heat treatment process. In this case, the average grain size of the middle layer 220 may be smaller than 215 Å described above.

In example embodiments, since the first blocking impurity-doped layer 210 has the average size of the grains which is smaller than that of the middle layer 220, an average strength of the first blocking impurity-doped layer 210 may be greater than that of the middle layer 220. In addition, since the second blocking impurity-doped layer 230 has the average size of the grains which is smaller than that of the first blocking impurity-doped layer 210, an average strength of the second blocking impurity-doped layer 210 may be greater than that of the first blocking impurity-doped layer 210. The term “average strength” of a material, as referred to here, may denote to the mean value of the maximum stress that a material can withstand before failure or yielding. As the average size of the grains of the blocking impurity-doped layer decreases, the number of grain boundaries increases, making deformation and failure of the blocking impurity-doped layer more difficult. As a result, the average strength of the blocking impurity-doped layer may increase.

As such, as blocking impurity-doped layers 210 and 230 are formed in the gate electrode structure 200, average strength of a layer may be increased, and etching resistance may be increased. Thus, a dent (i.e., depression) on the active area AC at both sides of the gate electrode structure 200 in the etching process, namely, the pitting may be prevented from occurring.

Particularly, according to the semiconductor device of example embodiments, although the gate insulating layer 100 is formed to have an extremely small thickness less than approximately 30 Å, occurrence of the dent on the active area AC of the substrate 10 in the etching process, namely, the pitting may be prevented in advance by securing a process margin with the second blocking impurity-doped layer 230 which is a blocking impurity-doped layer having a high concentration. Simultaneously, the first blocking impurity-doped layer 210 adjacent to the gate insulating layer 100 may be doped in the relatively low blocking impurity concentration. Through this, an increase in resistance of a layer may be maximally suppressed, and performance of the semiconductor device may be improved.

That is, in the gate electrode structure 200 according to example embodiments, a polysilicon layer adjacent to the gate insulating layer 100 (namely, the first blocking impurity-doped layer 210) may be doped with the blocking impurity in a relatively low concentration. Through this, the conductivity-type dopant may be prevented from penetrating into the gate insulating layer 100, and simultaneously, element performance may be improved. A polysilicon layer spaced far from the gate insulating layer 100 (namely, the second blocking impurity-doped layer 230) may be doped with the blocking impurity in a relatively high concentration. Through this, the pitting may be prevented in the etching process. Also, resistance of the gate electrode structure 200 may be maximally lowered by forming the middle layer 220 not doped with the blocking impurity between the first blocking impurity-doped layer 210 and the second blocking impurity-doped layer 230.

In example embodiments, the gate electrode structure 200 may further include the metallic conductive layer 240 disposed above the polysilicon layer. The metallic conductive layer 240 may be formed of tungsten (W) or tungsten silicide (WSiₓ, where the subscript “x” represents a variable number of silicon atoms present in the compound; that is, a non-fixed ratio of elements in the compound). However, a material of the metallic conductive layer 240 is not limited thereto. For example, the metallic conductive layer 240 may include at least one of a metal, a metal alloy, a conductive metal nitride, a metal silicide, a doped semiconductor material, a conductive metal oxide, and a conductive metal oxynitride. The metallic conductive layer 240 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but it is merely an example. The conductive metal oxide and the conductive metal oxynitride may include a form in which the above-described material is oxidized, but it is merely an example.

In example embodiments, the metallic conductive layer 240 may cover an upper surface of the second blocking impurity-doped layer 230. The term “cover” (or “covers,” or like terms), as may be used herein, is intended to broadly refer to an element, structure or layer that is on or over another element, structure or layer, either directly or with one or more other intervening elements, structures or layers therebetween. The metallic conductive layer 240 may have widths in a second direction (e.g., a D2 direction) and in a third direction (e.g., a D3 direction) perpendicular to the second direction that are approximately equal to those of the second blocking impurity-doped layer 230, respectively.

Meanwhile, although not explicitly illustrated in a drawing, the semiconductor device may further include an insulation spacer covering a side surface of the gate electrode structure 200.

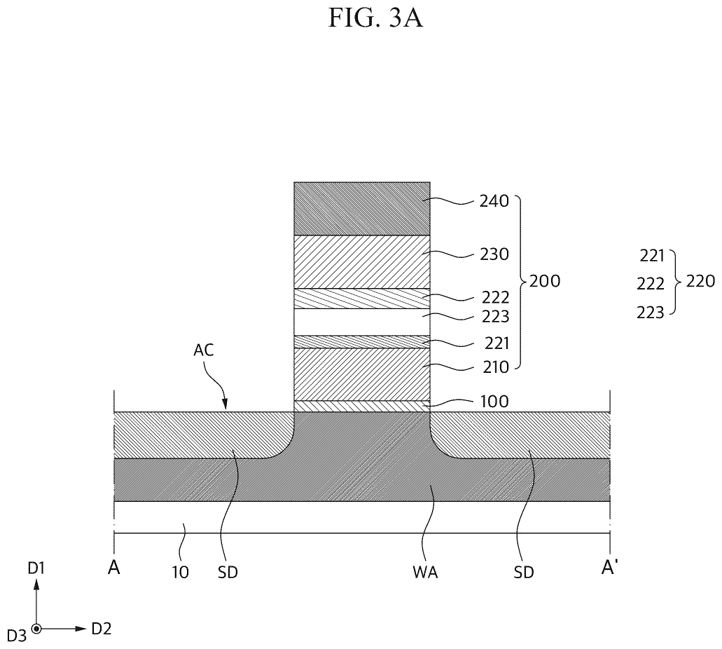

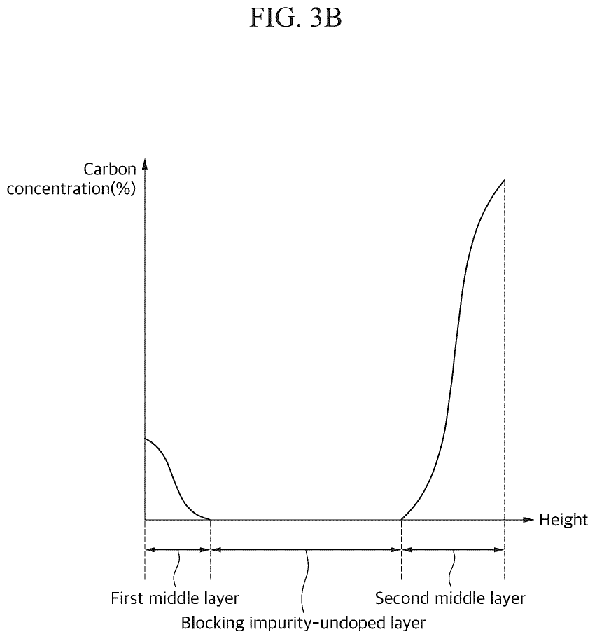

Hereinafter, the gate electrode structure 200 according to example embodiments will be described in detail with reference to FIGS. 3A and 3B.

FIG. 3A is an example schematic cross-sectional view taken along line A-A′ of FIG. 1.

FIG. 3B is a graph illustrating an example of a blocking impurity concentration (i.e., impurity doping profile) in the middle layer 220 of FIG. 3A.

Since a semiconductor device described through FIGS. 3A and 3B includes all characteristics of the semiconductor device described above through FIGS. 1 through 2B, redundant descriptions will be omitted.

In example embodiments, the gate insulating layer 100 and the gate electrode structure 200 may be disposed above the active area AC. The gate electrode structure 200 may include the first blocking impurity-doped layer 210 which is formed of polysilicon doped with a blocking impurity in a relatively low concentration, a second blocking impurity-doped layer 230 which is formed of polysilicon doped with the blocking impurity in a relatively high concentration, and the middle layer 220 which is formed of polysilicon disposed between the first blocking impurity-doped layer 210 and the second blocking impurity-doped layer 230. Here, descriptions of FIGS. 2A and 2B may be referenced for blocking impurity concentrations in the first blocking impurity-doped layer 210 and the second blocking impurity-doped layer 230.

In example embodiments, the first blocking impurity-doped layer 210 and the second blocking impurity-doped layer 230 may be crystalized into the polysilicon through a heat treatment in a subsequent process after being formed of amorphous silicon doped with the blocking impurity. In addition, the middle layer 220 may be crystallized into the polysilicon through a heat treatment in a subsequent process after being formed of amorphous silicon not doped with the blocking impurity. In such a heat treatment process, the blocking impurity with which the first blocking impurity-doped layer 210 and the second blocking impurity-doped layer 230 are doped may be distributed over at least some areas of the middle layer 220 by diffusing toward the middle layer 220.

For example, referring to FIG. 3A, the middle layer 220 may include a first middle layer 221 adjacent to the first blocking impurity-doped layer 210 and a second middle layer 222 adjacent to the second blocking impurity-doped layer 230. The first middle layer 221 and the second middle layer 222 may have the blocking impurity which is diffused from adjacent blocking impurity-doped layers 210 and 230, respectively.

In example embodiments, the middle layer 220 may further include a blocking impurity-undoped layer 223 to which the blocking impurity is not diffused. For example, referring to FIGS. 3A and 3B, the blocking impurity-undoped layer 223 which has an extremely low concentration of the blocking impurity or does not have the blocking impurity because the blocking impurity is not diffused may be formed between the first middle layer 221 and the second middle layer 222. Here, the first middle layer 221, the second middle layer 222, and the blocking impurity-undoped layer 223 may correspond to some areas distinguished in a vertical direction (e.g., a D1 direction) in the middle layer 220. In other words, a boundary line is illustrated for distinguishing the first middle layer 221, the second middle layer 222, and the blocking impurity-undoped layer 223 in FIG. 3A, but as the first middle layer 221, the second middle layer 222, and the blocking impurity-undoped layer 223 are individual areas in the middle layer 220, clear boundaries in between may not be formed as such.

In example embodiments, blocking impurity concentrations in the first middle layer 221 and the second middle layer 222 may be gradually decreased in directions away from the adjacent blocking impurity-doped layers. For example, referring to FIG. 3B, a blocking impurity concentration in first middle layer 221 may be continuously decreased in a first direction (e.g., the D1 direction in FIG. 3A) that is the vertical direction. Also, referring to FIG. 3B, a blocking impurity concentration in the second middle layer 222 may be continuously increased in the first direction (e.g., the D1 direction in FIG. 3A) that is the vertical direction.

In example embodiments, a blocking impurity doping concentration of the second blocking impurity doped layer 230 may be higher than that of the first blocking impurity-doped layer 210. Accordingly, an amount of the blocking impurity, which is more than that in an area adjacent to the first blocking impurity-doped layer 210, may be diffused farther in an area adjacent to the second blocking impurity-doped layer 230. For example, referring to FIG. 3A, the second middle layer 222 may be formed to be thicker, in the D1 direction, than the first middle layer 221, and accordingly, referring to FIG. 3B, the blocking impurity may be distributed in the second middle layer 222 more than in the first middle layer 221. In addition, in an equal distance, an average change rate of the blocking impurity concentration in the second middle layer 222 may be higher than an average change rate of the blocking impurity concentration in the first middle layer 221.

In example embodiments, thicknesses in the D1 (i.e., vertical) direction and blocking impurity distribution patterns of the first middle layer 221, the blocking impurity-undoped layer 223, and the second middle layer 222 of the middle layer 220 may be variously formed depending on a heating time or a heating temperature in the heat treatment process. For example, when the heating time is short in the heat treatment process, or when the heating temperature is low in the heat treatment process, an extremely small amount of the blocking impurity may be diffused, or the blocking impurity may not be diffused into the middle layer 220. Thus, while the impurity blocking undoped-layer 223 may be formed widely, the first middle layer 221 and the second middle layer 22 may formed narrowly. Alternatively, depending on conditions of the heat treatment process, the middle layer 220 may be formed of the blocking impurity-undoped layer 223 without the first middle layer 221 and the second middle layer 222.

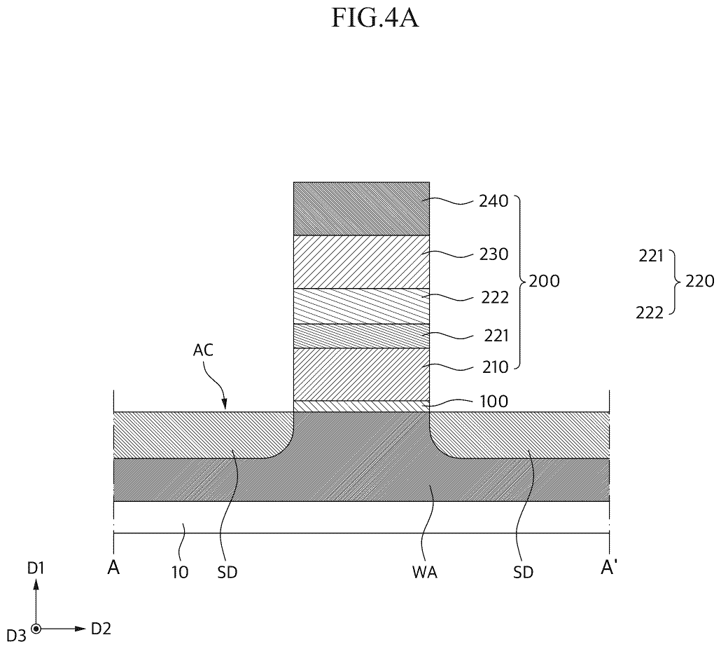

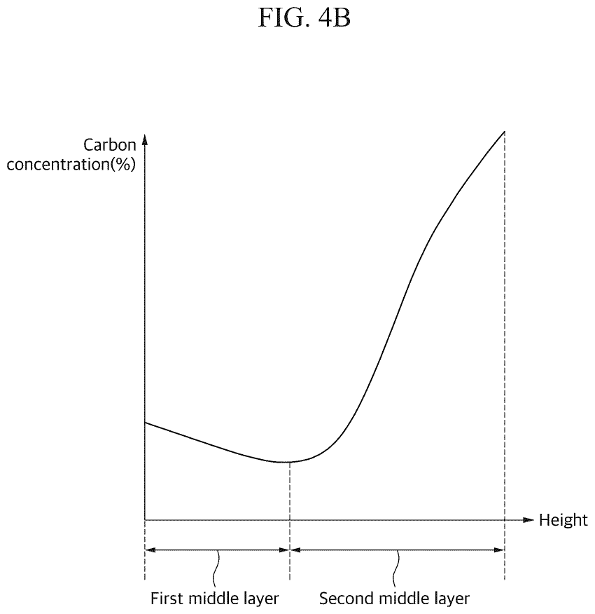

Alternatively, as illustrated in FIGS. 4A and 4B, the middle layer 220 may be formed of the first middle layer 221 and the second middle layer 222 without the blocking impurity-undoped layer 223.

FIG. 4A is an example schematic cross-sectional view taken along line A-A′ of FIG. 1.

FIG. 4B is a graph illustrating an example of a blocking impurity concentration (i.e., blocking impurity profile) in the middle layer 220 of FIG. 4A.

Referring to FIGS. 4A and 4B, the middle layer 220 may include the first middle layer 221 which is adjacent to the first blocking impurity-doped layer 210 in the gate electrode structure 200 and the second middle layer 222 which is adjacent to the second blocking impurity-doped layer 230. Blocking impurity concentrations in the first middle layer 221 and the second middle layer 222 may be gradually decreased in directions away from adjacent blocking impurity-doped layers 210 and 230, respectively. For example, referring to FIG. 4B, a blocking impurity concentration in the first middle layer 221 may be continuously increased in a direction toward the gate insulating layer 100 (namely, a direction toward the first blocking impurity- doped layer 210). Furthermore, referring to FIG. 4B, a blocking impurity concentration in the second middle layer 222 may be continuously decreased in the direction toward the gate insulating layer 100 (namely, a direction away from the second blocking impurity-doped layer 230).

In example embodiments, depending on conditions of a heat treatment process, and when a blocking impurity has been actively diffused, the middle layer 220 may have a layer structure in which the first middle layer 221 and the second middle layer 222 are continuously connected with each other without the blocking impurity-undoped layer 223. In this case, a point at which a blocking impurity concentration in a polysilicon layer is lowest may be formed in a boundary area between the first middle layer 221 and the second middle layer 222.

In example embodiments, a blocking impurity doping concentration of the second blocking impurity-doped layer 230 may be higher than that of the first blocking impurity-doped layer 210. Accordingly, an amount of the blocking impurity, which is more than that of the first middle layer 221, may be diffused farther in the second middle layer 222 adjacent to the second blocking impurity-doped layer 230. For example, referring to FIG. 4A, the second middle layer 222 may be formed to be thicker, in the D1 (i.e., vertical) direction, than the first middle layer 221, and referring to FIG. 4B, the blocking impurity may be distributed in the second middle layer 222 more than in the first middle layer 211. Also, in an equal distance, an average change rate of the blocking impurity concentration in the second middle layer 222 may be higher than an average change rate of the blocking impurity concentration in the first middle layer 221.

Meanwhile, descriptions of FIGS. 3A and 3B may be referenced for all other characteristics of a semiconductor device illustrated in FIGS. 4A and 4B except that the blocking impurity-undoped layer 223 is not formed in the middle layer 220.

FIG. 5 is an example schematic cross-sectional view illustrating a semiconductor device according to example embodiments.

A first transistor TR1 illustrated at a left side in FIG. 5 may show an example cross section taken along line A-A′ of FIG. 1. A second transistor TR2 illustrated at a right side in FIG. 5 may show an example cross section taken along line B-B′ of FIG. 1. However, positions at which the first transistor TR1 and the second transistor TR2 are disposed are not limited to an illustration in a drawing.

In example embodiments, the active area AC (see FIG. 1) of the semiconductor device may include a first active area AC1 and a second active area AC2 that are disposed in a direction parallel to the substrate 10; the first and second active areas AC1 and AC2, respectively, may be spaced apart from one another in the D3 direction, as shown in FIG. 1. Different gate electrode structures 201 and 202 may be disposed above the first active area AC1 and the second active area AC2, respectively, to form the first transistor TRI and the second transistor TR2.

In example embodiments, conductive impurities opposite to each other may be injected into the first active area AC1 and the second active area AC2. For example, referring to FIG. 5, a first well area WA1 doped with an n-type impurity and a first source/drain area SD1 doped with a p-type impurity may be disposed in the first active area AC1 of the semiconductor device, and the first gate electrode structure 201 doped with the p-type impurity may be disposed above the first active area AC1 to form a PMOS device. In addition, a second well area WA2 doped with the p-type impurity and a second source/drain area SD2 doped with the n-type impurity may be disposed above the second active area AC2 of the semiconductor device, and the second gate electrode structure 202 doped with the n-type impurity may be disposed above the second active area AC2 to form an NMOS device.

In example embodiments, the first gate electrode structure 201 and the second gate electrode structure 202 may have a layer stack structure identical to that of the gate electrode structure 200 which is described above with reference to FIGS. 1 through 4B. FIGS. 1 through 4B may be referenced for a detailed description thereof.

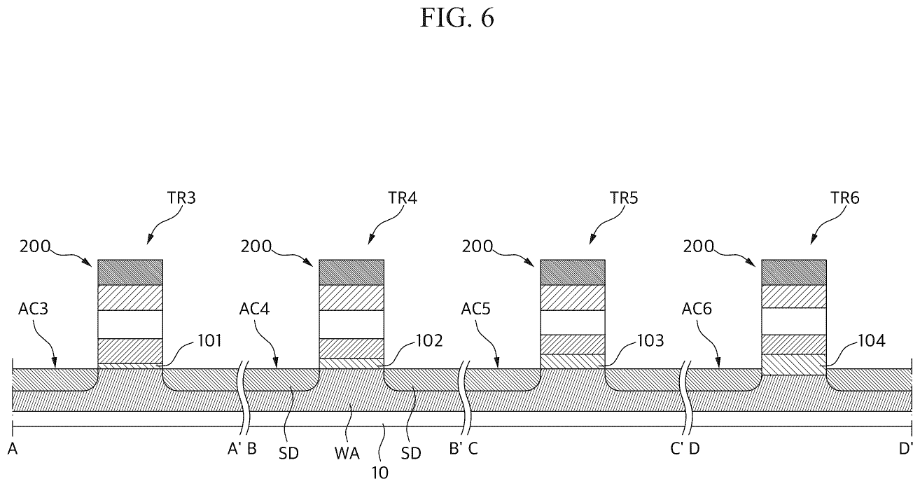

Also, as illustrated in FIG. 6, in example embodiments, the gate electrode structure 200 may be disposed above each of gate insulating layers 101, 102, 103, and 104 having different thicknesses in the vertical (i.e., D1) direction.

FIG. 6 is an example schematic cross-sectional view illustrating a semiconductor device according to example embodiments.

Third through sixth transistors TR3, TR4, TR5, and TR6 illustrated in FIG. 6 may show example cross sections taken along line A-A′, line B-B′, line C-C′, and line D-D′ of FIG. 1, respectively. However, positions at which the third through sixth transistors TR3, TR4, TR5, and TR6 are not limited to an illustration in a drawing.

Referring to FIG. 6, the gate insulating layers 101, 102, 103, and 104 of the semiconductor device may include first through fourth gate insulating layers 101, 102, 103, and 104, respectively, having different cross-sectional thicknesses while being disposed in a direction parallel to the substrate 10 (e.g., a D2 and/or D3 direction). For example, the semiconductor device may include the first through fourth gate insulating layers 101, 102, 103, and 104 which are formed on third through sixth active areas AC3, AC4, AC5, and AC6, respectively, formed at different positions on the substrate 10, and the gate electrode structure 200 may be respectively disposed above each of the gate insulating layers 101, 102, 103, and 104 to form the third through sixth transistors TR3, TR4, TR5, and TR6. Alternatively, at least two of the first through fourth gate insulating layers 101, 102, 103, and 104 may be disposed side by side on one active area extending in one direction.

In example embodiments, the thicknesses of the first through third gate insulating layers 101, 102, 103, and 104 in the vertical direction (i.e., D1 direction) may be different from each other. For example, a first gate insulating layer 101 may be formed to be thinner in the D1 direction than a second gate insulating layer 102. The second gate insulating layer 102 may be formed to be thinner in the D1 direction than a third gate insulating layer 103. The third gate insulating layer 103 may be formed to be thinner in the D1 direction than a fourth gate insulating layer 104. A thickness of the thinnest first gate insulating layer 101 may range approximately from 20 to 30 Å.

In example embodiments, at least one of the first through fourth gate insulating layers 101, 102, 103, and 104 may be formed below the gate electrode structure 200 which is connected with high-voltage wiring. For example, referring to FIG. 6, the fourth gate insulating layer 104 may be formed to be thicker, in the D1 (i.e., vertical) direction, than thicknesses of other gate insulating layers 101, 102, and 103 so that the gate electrode structure 200 which is disposed above may be implemented as a high-voltage gate. In order to minimize or remove a process step with another insulating layer, an upper surface of a portion at which the fourth gate insulating layer 104 may be formed in the sixth active area AC6 may be recessed further than another portion on the substrate 10.

In example embodiments, the gate electrode structure 200 disposed above each of the first through fourth gate insulating layers 101, 102, 103, and 104 may have a layer stack structure identical to that of the gate electrode structure 200 which is described above with reference to FIGS. 1 through 4B. FIGS. 1 through 4B may be referenced for a detailed description thereof.

In example embodiments, the gate electrode structure 200 may include a first blocking impurity-doped layer and a second blocking impurity-doped layer which are doped with a blocking impurity in different concentrations, and thus, pitting may be prevented from occurring in an etching process on the semiconductor substrate 10 on which the gate insulating layers 101, 102, 103, and 104, which have the different thicknesses in the D1 direction, including a thin gate insulating layer having a thickness less than or equal to 30 Å, are formed.

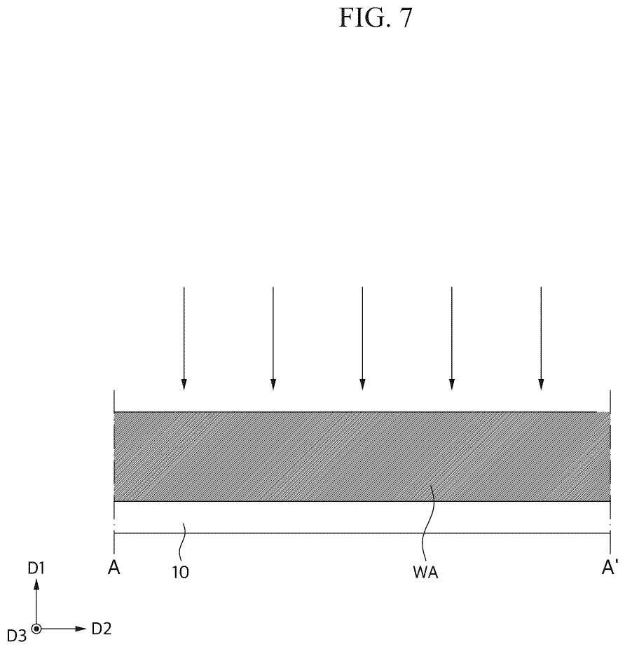

Hereinafter, a method of manufacturing the semiconductor device according to example embodiments will be described with reference to FIGS. 7 through 14.

FIGS. 7 through 14 are schematic cross-sectional views depicting intermediate processes in a method of manufacturing a semiconductor device according to example embodiments.

To begin with, referring to FIG. 7, the well area WA may be doped with a conductive impurity ion (e.g., using an ion implantation process, or the like) on the substrate 10 and formed. For example, the well area WA which is doped with an N-type dopant may be formed in order to form a PMOS, or the well area WA which is doped with a P-type dopant may be formed in order to form an NMOS.

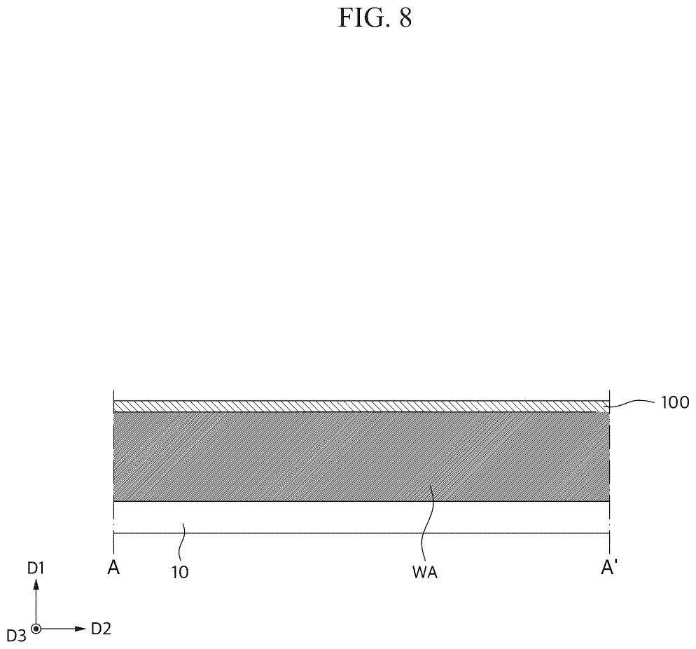

Referring to FIG. 8, the gate insulating layer 100 may be formed thinly on a surface of the active area AC through a thermal oxidation process. For example, the gate insulating layer 100 may be formed by using a method such as chemical vapor deposition or atomic layer deposition.

In example embodiments, the gate insulating layer 100 may be formed to have different thicknesses at different positions on the substrate 10. For example, a plurality of gate insulating layers (e.g., the gate insulating layers 101 through 104 of FIG. 6) having different thicknesses in the D1 direction may be formed at different positions on the substrate 10. A gate insulating layer having a smallest average thickness among a plurality of gate insulating layers 100 formed as such may be formed to have a thickness less than or equal to 30 Å.

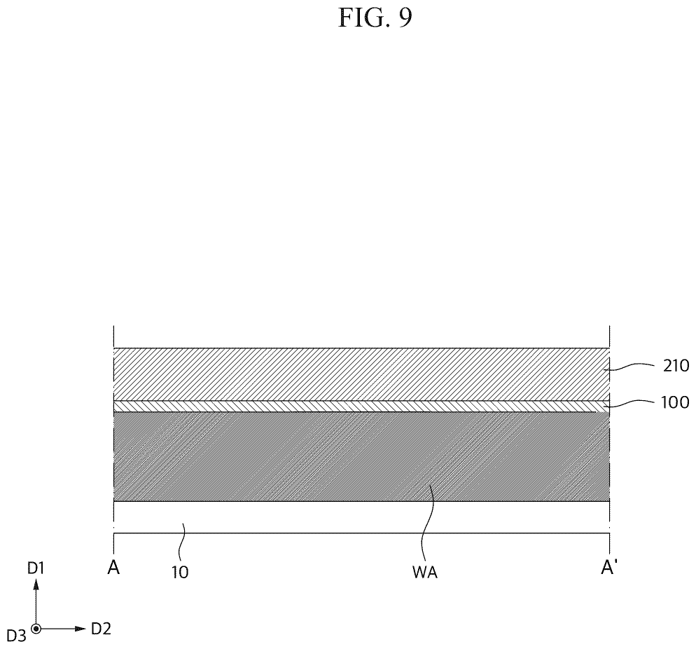

Referring to FIGS. 9 through 11, each layer forming a portion of the gate electrode structure 200 above the gate insulating layer 100 may be formed by depositing a polysilicon layer (or multiple polysilicon layers).

Referring to FIG. 9, the first blocking impurity-doped layer 210 may be formed above the gate insulating layer 100. While the polysilicon layer is deposited, the first blocking impurity-doped layer 210 may be doped with an n-type or p-type dopant and a blocking impurity and formed. For example, an inside of the polysilicon layer may be doped in situ with the blocking impurity by supplying a gas containing the blocking impurity together with a silicon source gas. At this point, the blocking impurity may be a material including at least one of carbon or germanium, although embodiments are not limited thereto.

In example embodiments, a blocking impurity concentration in the first blocking impurity-doped layer 210 may be formed to be less than or equal to three percent or desirably less than or equal to approximately one percent. The blocking impurity concentration in the first blocking impurity-doped layer 210 may be controlled by a supply time and a supply amount of the gas containing the blocking impurity. As the inside of the polysilicon layer is doped with the blocking impurity as such, a dopant (e.g., boron) may be prevented from penetrating into the gate insulating layer 100. Furthermore, since the first blocking impurity-doped layer 210 has a low blocking impurity concentration less than or equal to approximately one percent, an increase in resistance of the layer may be maximally suppressed, and performance of the semiconductor device may be improved.

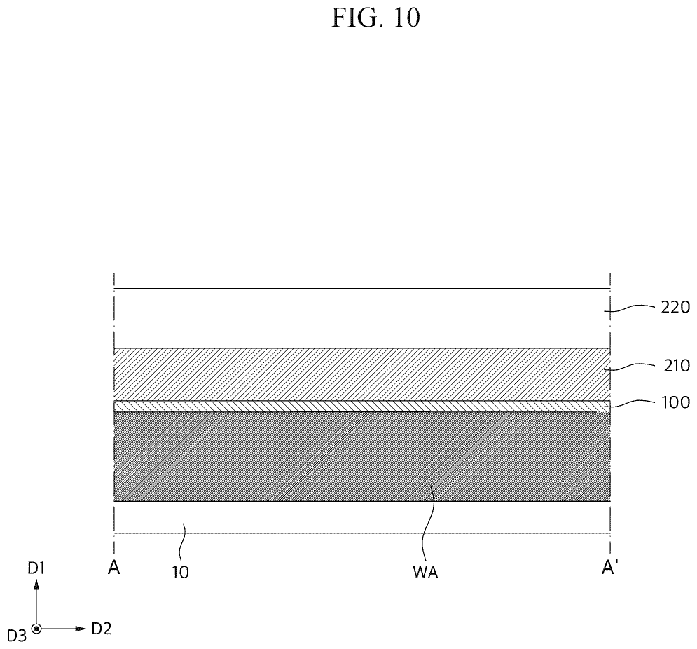

Referring to FIG. 10, the middle layer 220 may be formed above the first blocking impurity-doped layer 210 by stopping supply of the gas containing the blocking impurity and depositing in situ the polysilicon layer which is doped with a conductive impurity. A grain size of the middle layer 220 which is undoped with the blocking impurity may be larger than a grain size of the first blocking impurity-doped layer 210 which is doped with the blocking impurity.

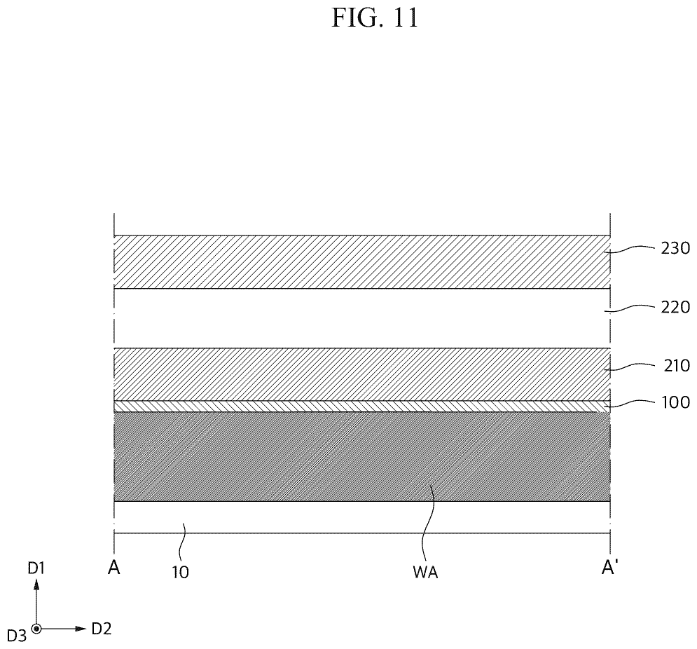

Referring to FIG. 11, the second blocking impurity-doped layer 230 which is doped with the blocking impurity may be formed above the middle layer 220. Similarly to the first blocking impurity-doped layer 210, while the polysilicon layer is deposited, the second blocking impurity-doped layer 230 may be doped with the n-type or p-type dopant and the blocking impurity and formed. For example, an inside of the polysilicon layer may be doped in situ with the blocking impurity by supplying the silicon source gas and the gas containing the blocking impurity. A blocking impurity concentration in the second blocking impurity-doped layer 230 may be formed to be greater than or equal to three percent or desirably be approximately five percent. The blocking impurity concentration in the second blocking impurity-doped layer 230 may be controlled by a supply time and a supply amount of the gas containing the blocking impurity. A grain size of the second blocking impurity-doped layer 230 which is doped with the blocking impurity in a concentration higher than that in the first blocking impurity-doped layer 210 may be smaller than the grain size of the first blocking impurity-doped layer 210. The second blocking impurity-doped layer 230 may have strength greater than that of the first blocking impurity-doped layer 210. The second blocking impurity-doped layer 230 which is formed to have relatively great strength as such may have a stronger tolerance in an etching process, and thus, pitting may be prevented from occurring in the active area AC at both sides of the gate electrode structure 200 in the etching process.

In example embodiments, each polysilicon layer forming at least a portion of the gate electrode structure 200 may be crystallized into polysilicon through a heat treatment in a subsequent process after being formed of amorphous silicon. For example, the first blocking impurity-doped layer 210 and the second blocking impurity-doped layer 230 may be crystallized into the polysilicon through a heat treatment in a subsequent process after being formed of amorphous silicon doped with the blocking impurity. Also, the middle layer 220 may be crystallized into the polysilicon through a heat treatment in a subsequent process after being formed of amorphous silicon which is not doped with the blocking impurity.

In example embodiments, during a heat treatment process, the blocking impurity which is contained in the first blocking impurity-doped layer 210 and the second blocking impurity-doped layer 230 may be diffused into a nearby layer (e.g., the middle layer 220). Accordingly, at least a portion of the middle layer 220 may include a first middle layer (e.g., the first middle layer 221 of FIG. 3A or 4A) and a second middle layer (e.g., the second middle layer 222 of FIG. 3A or 4A) that contain a small amount of the blocking impurity (i.e., less than that of the adjacent blocking impurity-doped layer). In addition, the middle layer 220 may further include a blocking impurity-undoped layer (e.g., the blocking impurity-undoped layer 223 of FIG. 3A) that does not have the blocking impurity because the blocking impurity which is contained in the first blocking impurity-doped layer 210 and the second blocking impurity-doped layer 230 is not transferred. For example, when a rapid heat treatment process or a low-temperature heat treatment process is performed in a subsequent process, the blocking impurity-undoped layer 223 which does not contain the blocking impurity may be formed in the middle layer 220 as diffusion of the blocking impurity is suppressed. However, a distribution of the blocking impurity in the middle layer 220 is not limited to the above description. For example, the entire middle layer 220 may be formed as the blocking impurity-doped layer by appropriately adjusting heat treatment process conditions.

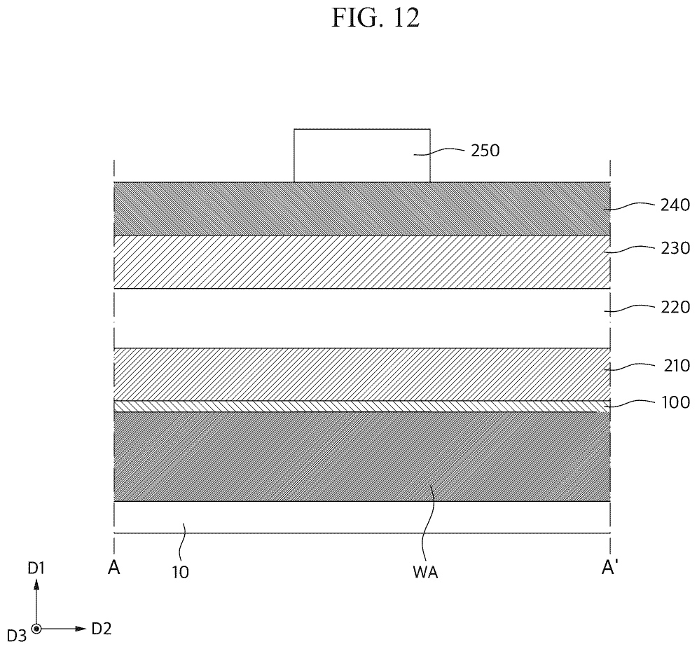

Referring to FIG. 12, the metallic conductive layer 240 may be formed above the second blocking impurity-doped layer 230. The metallic conductive layer 230 may be formed of tungsten (W) or tungsten silicide (WSix), but a detailed material thereof is not limited thereto.

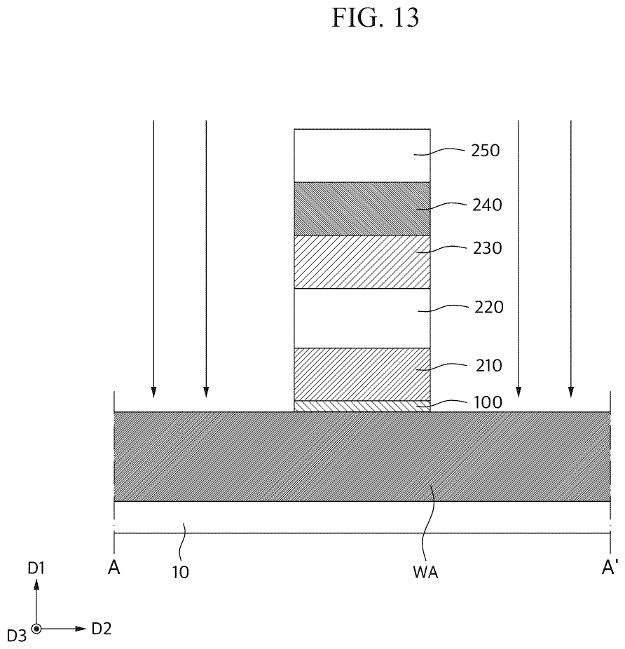

Referring to FIGS. 12 and 13, the metallic conductive layer 240, the second blocking impurity-doped layer 230, the middle layer 220, the first blocking impurity-doped layer 210, and the gate insulating layer 100 may be etched by using, as an etching mask, a hard mask 250 formed above the metallic conductive layer 240. Accordingly, a gate electrode structure in which the first blocking impurity-doped layer 210, the middle layer 220, the second blocking impurity-doped layer 230, and the metallic conductive layer 240 are stacked on the gate insulating layer 100 on the active area AC in the D1 direction may be formed.

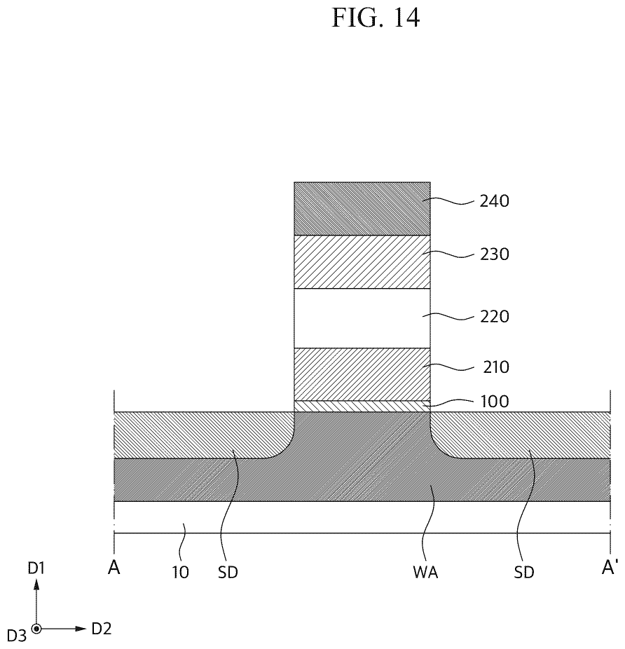

Referring to FIGS. 13 and 14, the pair of source/drain areas SD may be formed by injecting, into the active area AC at both sides of the gate electrode structure, a conductive dopant having a polarity opposite to that of a dopant with which the well area WA is doped. The hard mask 250 may then be removed, with the resulting structure shown in FIG. 14. Afterward, a transistor may be formed by forming a contact plug (not illustrated) that is in contact with each of the source/drain areas SD. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

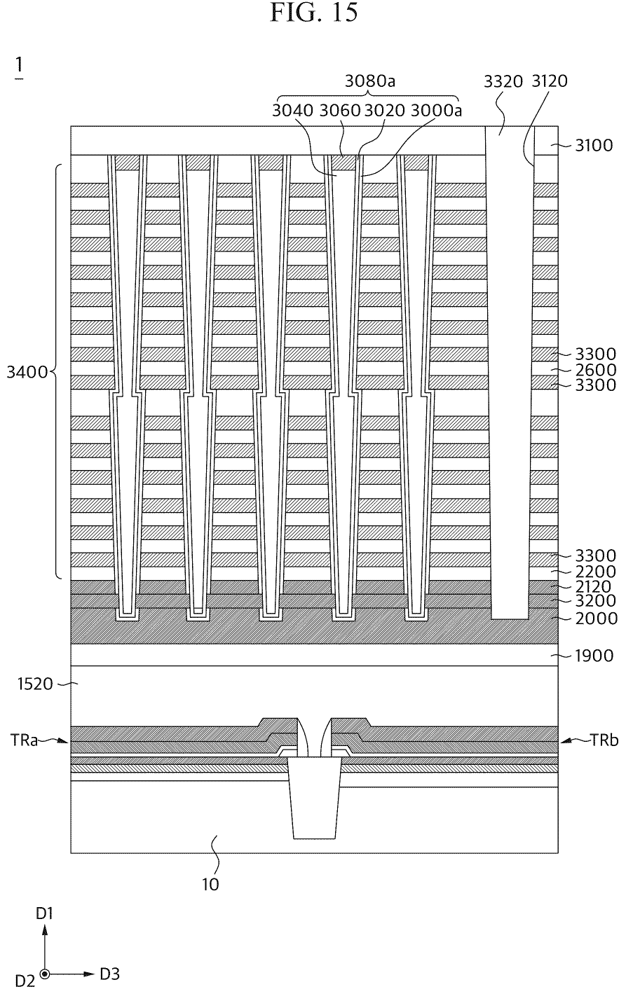

The transistor according to example embodiments may be applied to a vertical-type semiconductor device 1 (see FIG. 15). Hereinafter, the vertical-type semiconductor device 1 according to example embodiments will be described with reference to FIG. 15.

FIG. 15 is an example schematic cross-sectional view illustrating the vertical-type semiconductor device 1 according to example embodiments.

A semiconductor device 1 according to example embodiments, which is the vertical-type semiconductor device 1, may be a NOT-AND (NAND) flash memory element.

Referring to FIG. 15, the semiconductor device 1 may have a cell-on-peri (COP) structure in which a peripheral circuit is formed on the substrate 10, and stacked memory cells are provided on the peripheral circuit.

In example embodiments, the plurality of transistors TR which is described above through FIGS. 1 through 14 may be provided on the peripheral circuit. For example, transistors TRa and TRb may each correspond to at least one of a plurality of transistors TR3, TR4, TR5, and TR6 described in FIG. 6. The peripheral circuit may further include lower wiring electrically connected with the plurality of transistors TRa and TRb.

In example embodiments, upper sides of the plurality of transistors TRa and TRb may be covered with a first inter-layer insulation film 1520. A second inter-layer insulation film 1900 may be further provided on the first inter-layer insulation film 1520.

In example embodiments, the memory cells may be provided on the plurality of transistors TRa and TRb. For example, the memory cells may be formed on the second inter-layer insulation film 1900.

Hereinafter, an example configuration of a memory cell included in the semiconductor device 1 according to an example embodiment will be described.

In example embodiments, a base semiconductor pattern 2000 may be provided on the second inter-layer insulation film 1900. The base semiconductor pattern 2000 may include, for example, polysilicon.

In example embodiments, a channel connection pattern 3200 and a support film 2120 may be sequentially provided on the base semiconductor pattern 2000; that is, the support film 2120 may be disposed on the channel connection pattern 3200. A cell stack structure 3400 may be provided on the support film 2120. The cell stack structure 3400 may have a structure in which insulation films 2200 and 2600 and gate patterns 3300 are alternately and repeatedly stacked in the vertical direction (i.e., D1 direction).

In example embodiments, a plurality of cell stack structures 3400 may be spaced apart in a first direction (e.g., a D1 direction). A first trench 3120 extending in the first direction (e.g., the D1 direction) may be disposed between the plurality of cell stack structures 3400. An inside of the first trench 3120 may be filled with a separation film pattern 3320.

In example embodiments, channel holes exposing an upper surface of the base semiconductor pattern 2000 by penetrating (i.e., extending in) the cell stack structure 3400 may be provided. The term “exposing” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. A channel structure 3080a may be provided in each of the channel holes. The channel structure 3080a may include an electrical charge storage structure 3000a, a channel 3020, a buried insulation pattern 3040, and a capping pattern 3060.

In example embodiments, the electrical charge storage structure 3000a may be in contact with a side wall of a channel hole. The electrical charge storage structure 3000a may include a first blocking film, an electrical charge storage film, and a tunnel insulation film stacked in sequential order on the side wall of the channel hole. The channel 3020 may be in contact with the tunnel insulation film and electrically connected with the base semiconductor pattern 2000. A side wall of the channel 3020 may be in contact with the channel connection pattern 3200. An outer side wall, which is opposite to the channel connection pattern 3200 of the channel 3020 may have a shape in which the tunnel insulation film, the electric charge storage film, and the first blocking film are partially removed. The channel 3020 may be electrically connected with the base semiconductor pattern 2000 through the channel connection pattern 3200. The buried insulation pattern 3040 may be provided on the channel 3020 and fill an inside of the channel hole.

In example embodiments, a first upper inter-layer insulation film 3100 covering the cell stack structure 3400 and the channel structure 3080a may be provided. The first upper inter-layer insulation film 3100 may include silicon oxide. The first trench 3120 may extend from the first upper inter-layer insulation film 3100 to an upper part of the channel connection pattern 3200 in a vertical direction.

As such, in the vertical-type semiconductor device 1 according to example embodiments, peripheral circuits including the transistors TRa and TRb may be formed on the substrate 10, and then, inter-layer insulation films 1520 and 1900 covering the transistors TRa and TRb may be formed. In addition, the memory cells may be formed on the inter-layer insulation films 1520 and 1900. At this point, the transistor TRa and TRb may be formed with a process identical to that described above with reference to FIGS. 7 through 14.

The various example embodiments of the present disclosure have been described above in detail, but the scope of the present disclosure is not limited thereto. It will be apparent to those skilled in the art that various changes and modifications may be allowed within the scope of the technical spirit of the present disclosure. In addition, the above-described example embodiments may be implemented without a portion of elements thereof, and each of the example embodiments may be implemented in combination with another.

What is claimed is:

1. A semiconductor device, comprising:
an active area on a substrate;
a gate insulating layer on the active area; and
a gate electrode structure on the gate insulating layer,
wherein the gate electrode structure comprises:
a first blocking impurity-doped layer in contact with an upper surface of the gate insulating layer and doped with a blocking impurity;
a middle layer on the first blocking impurity-doped layer; and
a second blocking impurity-doped layer on the middle layer and doped with the blocking impurity, and
a blocking impurity concentration in the second blocking impurity-doped layer is greater than a blocking impurity concentration in the first blocking impurity-doped layer.

2. The semiconductor device of claim 1, wherein the middle layer comprises a blocking impurity-undoped layer substantially free of the blocking impurity.

3. The semiconductor device of claim 1, wherein the blocking impurity comprises at least one of carbon or germanium.

4. The semiconductor device of claim 1, wherein the middle layer comprises:
a first middle layer adjacent to the first blocking impurity-doped layer; and
a second middle layer adjacent to the second blocking impurity-doped layer, and
a blocking impurity concentration in the first middle layer is continuously increased in a direction toward the gate insulating layer.

5. The semiconductor device of claim 4, wherein a blocking impurity concentration in the second middle layer is continuously decreased in the direction toward the gate insulating layer.

6. The semiconductor device of claim 4, wherein a thickness of the second middle layer in a first direction perpendicular to an upper surface of the substrate is greater than a thickness of the first middle layer in the first direction.

7. The semiconductor device of claim 1, wherein the blocking impurity concentration in the first blocking impurity-doped layer is less than or equal to one percent.

8. The semiconductor device of claim 7, wherein the blocking impurity concentration in the second blocking impurity-doped layer ranges from about one percent to five percent.

9. The semiconductor device of claim 8, wherein the first blocking impurity-doped layer comprises first grains,
the second blocking impurity-doped layer comprises second grains, and
an average size of the second grains is smaller than an average size of the first grains.

10. The semiconductor device of claim 1, wherein the gate insulating layer includes a first gate insulating layer and a second gate insulating layer that have different thicknesses in a first direction perpendicular to an upper surface of the substrate while being spaced from one another in a second direction parallel to the upper surface of the substrate,
the gate electrode structure is on each of the first gate insulating layer and the second gate insulating layer, and
a thickness in the first direction of at least one of the first gate insulating layer or the second gate insulating layer is less than or equal to 30 angstroms (Å).

11. The semiconductor device of claim 1, wherein the active area includes:
a first active area comprising a source/drain area having a p-type impurity; and
a second active area comprising a source/drain area having an n-type impurity, and
the gate electrode structure is on each of the first active area and the second active area.

12. The semiconductor device of claim 1, wherein the gate electrode structure further comprises a metallic conductive layer on the second blocking impurity-doped layer.

13. A semiconductor device, comprising:
an active area on a substrate;
a gate insulating layer on the active area; and
a gate electrode structure comprising a polysilicon layer on the gate insulating layer,
wherein the polysilicon layer of the gate electrode structure comprises:
a lower area in contact with an upper surface of the gate insulating layer and comprising a blocking impurity at a first concentration level;
an upper area on the lower area and comprising the blocking impurity at a second concentration level; and
a middle area between the upper area and the lower area,
the first concentration level is higher than a blocking impurity concentration level in the middle area, and
the second concentration level is higher than the first concentration level.

14. The semiconductor device of claim 13, wherein the first concentration level is less than or equal to one percent, and
the second concentration level ranges from three percent to five percent.

15. The semiconductor device of claim 13, wherein a thickness of at least a portion of the gate insulating layer under the gate electrode structure, in a first direction perpendicular to an upper surface of the substrate, is less than or equal to 30 angstroms (Å).

16. The semiconductor device of claim 13, further comprising a memory cell on the gate electrode structure.

17. A semiconductor device, comprising:
an active area on a substrate;
a gate insulating layer on the active area; and
a gate electrode structure on the gate insulating layer,
wherein the gate electrode structure comprises:
a first blocking impurity-doped layer on the gate insulating layer and doped with a blocking impurity;
a middle layer on the first blocking impurity-doped layer; and
a second blocking impurity-doped layer on the middle layer and doped with the blocking impurity,
the first blocking impurity-doped layer comprises first grains,
the second blocking impurity-doped layer comprises second grains, and
an average size of the second grains is smaller than an average size of the first grains.

18. The semiconductor device of claim 17, wherein the middle layer comprises third grains, and
an average size of the third grains is larger than the average size of the first grains.

19. The semiconductor device of claim 17, wherein an average strength of the first blocking impurity-doped layer is greater than an average strength of the second blocking impurity-doped layer.

20. The semiconductor device of claim 17, wherein the gate insulating layer comprises a first gate insulating layer and a second gate insulating layer, the first and second gate insulating layers having different thicknesses, in a first direction perpendicular to an upper surface of the substrate, while being spaced apart from one another in a second direction parallel to the upper surface of the substrate,
the gate electrode structure is on each of the first gate insulating layer and the second gate insulating layer, and
a thickness in the first direction of at least one of the first gate insulating layer or the second gate insulating layer is less than or equal to 30 angstroms (Å).
